(19) United States
(12) Patent Application Publication
(10) Pub. No.: US 2008/0029843 A1
(43) Pub. Date: Feb. 7, 2008

(54) E-Fuse and Method for Fabricating E-Fuses Integrating Polysilicon Resistor Masks

(75) Inventors: Roger Allen Booth JR., Wappingers Falls, NY (US); William Paul Hovis, Rochester, MN (US); Jack Allan Mandelman, Flat Rock, NC (US); William Robert Tonti, Essex Junction, VT (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, Armonk, NY (US)

(21) Appl. No.: 11/873,197

(22) Filed: Oct. 16, 2007

Related U.S. Application Data
(63) Continuation of application No. 11/382,808, filed on May 11, 2006.

(51) Int. Cl. H01L 29/41

(52) U.S. Cl. 257/529; 257/E25.001

(57) ABSTRACT

An E-fuse and a method for fabricating an E-fuse integrating polysilicon resistor masks, and a design structure on which the subject E-fuse circuit resides are provided. The E-fuse includes a polysilicon layer defining a fuse shape including a cathode, an anode, and a fuse neck connected between the cathode and the anode silicide formation. A silicide formation is formed on the polysilicon layer with an unsilicided portion extending over a portion of the cathode adjacent the fuse neck. The unsilicided portion substantially prevents current flow in the silicide formation region of the cathode, with electromigration occurring in the fuse neck during fuse programming. The unsilicided portion has a substantially lower series resistance than the series resistance of the fuse neck.

This application is a continuation-in-part application of Ser. No. 11/382,808 filed on May 11, 2006.

### FIELD OF THE INVENTION

The present invention relates generally to the field of manufacturing semiconductor devices, and more particularly, relates to an E-fuse and a method for fabricating the E-fuse integrating polysilicon resistor masks for improved fuse performance, and a design structure on which the subject E-fuse circuit resides.

### DESCRIPTION OF THE RELATED ART

Various semiconductor fuse arrangements and methods are known for fabricating semiconductor fuses and E-fuse elements.

For example, U.S. Pat. No. 6,624,499 discloses a method of programming via electromigration. A semiconductor fuse, which includes a cathode and an anode coupled by a fuse link having an electrically conductive component, such as silicide, is coupled to a power supply. A potential is applied across the conductive fuse link via the cathode and anode in which the potential is of a magnitude to initiate electromigration of silicide from a region of the semiconductor fuse reducing the conductivity of the fuse link. The electromigration is enhanced by effectuating a temperature gradient between the fuse link and one of the cathode and anode responsive to the applied potential. Portions of the semiconductor fuse are selectively cooled in a heat transfer relationship to increase the temperature gradient. In one embodiment, a heat sink is applied to the cathode. The heat sink can be a layer of metal coupled in close proximity to the cathode while insulated from the fuse link. In another embodiment, the temperature gradient is increased by selectively varying the thickness of the underlying oxide layer such that the cathode is disposed on a thinner layer of oxide than the fuse link.

U.S. Pat. No. 5,708,291 discloses a fusible link device disposed on a semiconductor substrate for providing discretionary electrical connections. The fusible link device includes a silicide layer and a polysilicon layer formed on the silicide layer and has a first un-programmed resistance. The silicide layer agglomerates to form an electrical discontinuity in response to a predetermined programming potential being applied across the silicide layer, such that the resistance of the fusible link device can be selectively increased to a second programmed resistance.

U.S. Pat. No. 6,580,156 discloses an integrated fuse having regions of different doping located within a fuse neck. The integrated fuse includes a polysilicon layer and a silicide layer. The polysilicon layer includes first and second regions having different types of dopants. In one example, the first region has an N-type dopant and the second region has a P-type dopant. The polysilicon layer can also include a third region in between the first and second regions, which also has a different dopant. During a fusing event, a distribution of temperature peaks around the regions of different dopants. By locating regions of different dopants within the fuse neck, agglomeration of the silicide layer starts reliably within the fuse neck, for example, at or near the center of the fuse neck, and proceeds toward the contact regions. An improved post fuse resistance distribution and an increased minimum resistance value in the post fuse resistance distribution are realized compared to conventional polysilicon fuses.

U.S. Pat. No. 6,507,087 discloses a fusible link device comprising a poly layer having a center undoped portion and two doped end portions. The center undoped portion having a first resistance and the two doped end portions each having a second resistance that is lower than the first resistance. A silicide layer is formed over the poly layer with the silicide layer having a third resistance lower than the second resistance. The resistance of the fusible link device can be selectively increased with the silicide layer agglomerating to form an electrical discontinuity within a discontinuity area in response to a predetermined programming potential being applied across the silicide layer. The agglomeration of the silicide layer occurring over the center undoped portion of the poly layer. Contacts are electrically coupled to the two doped poly layer end portions for receiving the programming potential.

FIG. 1 illustrates a prior art E-fuse including a cathode and an anode with a long, narrow fuse link or neck, shown separated from the cathode after the E-fuse has been blown. The illustrated prior art E-fuse is known CMOS technology that is currently suffering from very low post-blow fuse resistance, for example, with a mean post-blow resistance for some conditions of interest in the neighborhood of 2000 ohms, and often showing distributions with tails going much lower. This post-blow fuse resistance lowers the margin of the sensing circuit and thus negatively affects product reliability and yield. A higher post-blow fuse resistance is desired.

Examination of failure analysis (FA) data on the fuse elements after the fuse elements have been blown indicates that the electromigration (EM) of the silicide is not happening in the desired location, for example, as illustrated in FIG. 1. In the illustrated prior art E-fuse, too much silicide is taken from the U-shaped portion of the cathode and not enough silicide is taken from the neck. In the CMOS E-fuse design as illustrated in FIG. 1, EM in the cathode rather than in the neck of the E-fuse element causes the low post-programmed fuse resistance.

Generally it is desirable that the long, narrow neck area be free of silicide in a defined region of the neck after the fuse has blown. This provides a very high post-blow resistance. The blown fuse illustrated in FIG. 1 has a much lower post-blow resistance, such as lower than 1500 ohms, since the fuse has a very wide path through the poly where the silicide has been removed and a highly conductive path through the silicide in the neck area.

FIG. 2 is a chart illustrating post program resistance relative to a silicide migration length for prior art fuse elements indicated by reference points A, B, and C. As shown, the post-blow resistance of the fuse is a direct function of the amount of silicide that has been removed from the neck area of the fuse element.

A need exists for an improved E-fuse having high post-blow fuse resistance and that has a generally simple and cost effective fabricating process.

### SUMMARY OF THE INVENTION

Principal aspects of the present invention are to provide an E-fuse and a method for fabricating the E-fuse integrating polysilicon resistor masks, and a design structure on which the subject E-fuse circuit resides. Other important aspects of the present invention are to provide such E-fuse and method for fabricating substantially without negative effect and that overcome many of the disadvantages of prior art arrangements.

In brief, an E-fuse and a method for fabricating an E-fuse integrating polysilicon resistor masks, and a design structure on which the subject E-fuse circuit resides are provided. The E-fuse includes a polysilicon layer defining a fuse shape including a cathode, an anode, and a fuse neck connected between the cathode and the anode silicide formation. A silicide formation is formed on the polysilicon layer with an unsilicided portion extending over a portion of the cathode adjacent the fuse neck. The unsilicided portion substantially prevents current flow in the silicide formation region of the cathode, with electromigration occurring in the fuse neck during fuse programming.

In accordance with features of the invention, the unsilicided portion has a substantially lower series resistance than the series resistance of the fuse neck. The unsilicided portion has a defined size for providing a predefined series resistance of the unsilicided portion, whereby electromigration of the silicide layer occurs in the fuse neck and electromigration of the silicide layer is avoided in the cathode when a programming potential is applied across the silicide formation.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 illustrates a prior art fuse element after the fuse element has been blown where electromigration (EM) of the silicide is not occurring in the desired narrow neck location;

FIG. 2 is a chart illustrating prior art post program resistance relative to silicide migration length of prior art fuses elements;

FIG. 3 illustrates not to scale an exemplary E-fuse in accordance with the preferred embodiment;

FIGS. 4, 5, 6, 7 illustrate not to scale exemplary E-fuse fabrication sequence for fabricating the exemplary E-fuse of FIG. 3 integrating polysilicon resistor masks in accordance with the preferred embodiment;

FIG. 8 is a cross sectional view not to scale of the exemplary E-fuse of FIG. 3 in accordance with the preferred embodiment;

FIG. 9 illustrates another exemplary E-fuse fabricated by integrating polysilicon resistor masks in accordance with the preferred embodiment; and

FIG. 10 is a flow diagram of a design process used in semiconductor design, manufacturing, and/or test.

### DETAILED DESCRIPTION OF THE PREFERRED EMBODIMENTS

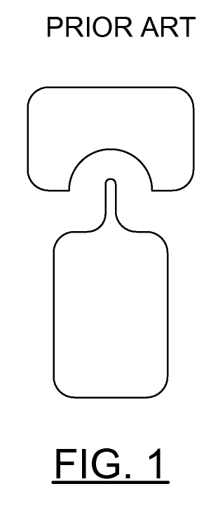

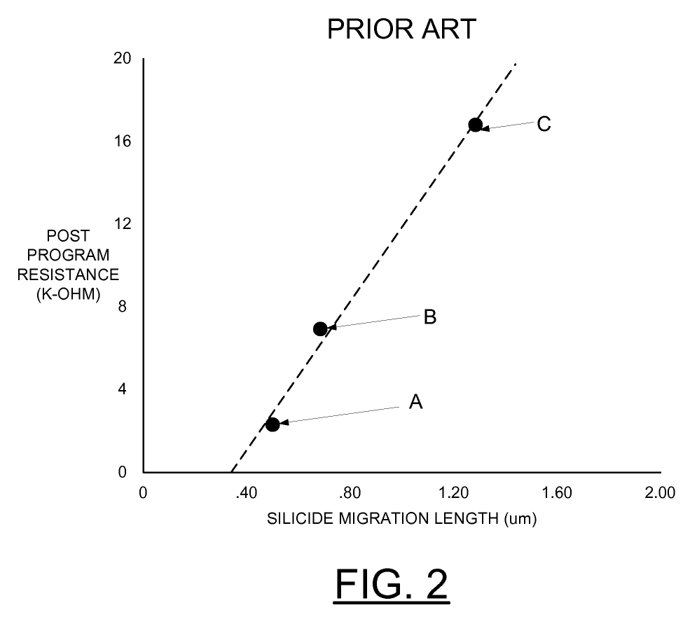

In accordance with features of the preferred embodiments, E-fuses are provided that eliminate low post-programmed fuse resistance caused by EM in the cathode rather than in the neck of the fuse element of prior art E-fuse designs, such as illustrated in FIG. 1. E-fuses of the preferred embodiments are fabricated by integrating polysilicon resistor masks without adding additional masks to the process. E-fuses of the preferred embodiments are fabricated using poly-resistor silicide-blocking and implant masks.

In accordance with features of the preferred embodiments, E-fuses are provided that do not to add any additional masks to a resistor processing sequence, for example, for CMOS technology.

In accordance with features of the preferred embodiments, the fabrication process for the E-fuses of the preferred embodiments use poly-resistor silicide-blocking and implant masks that are used in known CMOS technology, so E-fuses of the preferred embodiments advantageously are easily implemented with available CMOS technology.

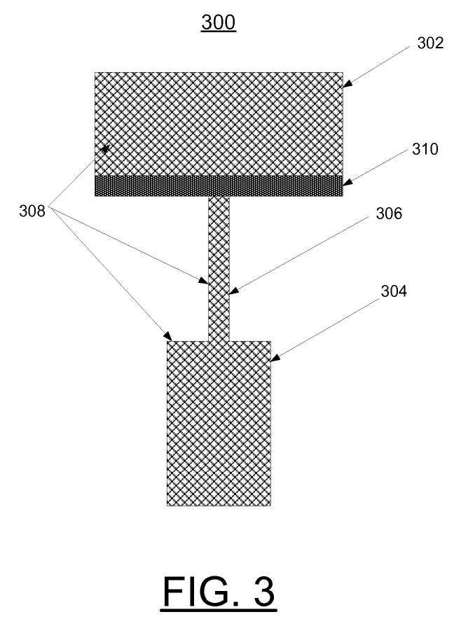

Having reference now to the drawings, in FIG. 3, there is shown an exemplary E-fuse generally designated by the reference character 300 in accordance with the preferred embodiment. E-fuse 300 includes a cathode 302, an anode 304, and a narrow fuse neck or fuse element 306 connected between the cathode 302 and the anode 304. A formation of silicide generally designated by the reference character 308 is formed everywhere except for a portion 310 of the wide cathode 302 closest to the narrow fuse element 306. The silicide 308 is indicated by crosshatched lines, and the unsilicided cathode portion 310 is indicated by dots.

In accordance with features of the preferred embodiments, the unsilicided portion 310 of the cathode 302 is made sufficiently wide and short such that its series resistance is small relative to the narrow fuse element 306.

Consider, for example, an unsilicided portion 310 of the cathode 302 having 0.05 squares and a fuse element of 100 squares. For the unsilicided portion 310 having a sheet resistance or sheet rho of 350 ohms/sq and the silicided portion 308 having a sheet rho of 8 ohms/sq, the resistance of the fuse element 306 is nearly 50× greater than the cathode portion 310. This results in the E-fuse 300 reliably blowing in the narrow fuse element 306, because electromigration of the silicide occurs in the fuse element 306 instead of across the gap 310 in the cathode 302 when a programming potential is applied across the silicide formation.

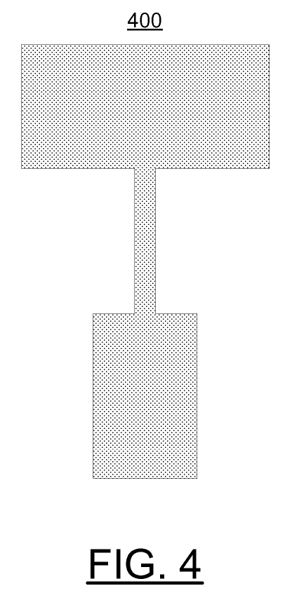

Referring now to FIGS. 4, 5, 6, and 7, there are shown exemplary process steps for fabricating E-fuse 300 in accordance with the preferred embodiment. E-fuse 300 is particularly attractive, since it does not require any new masks. Only the standard masks that are normally used to define polysilicon resistors along with a silicidation inhibit mask are required.

Two masks used to make the polysilicon resistor do the following: First a first mask opens the resistor area to a heavy P+ implant, and in addition to the P+ source-drain-gate implant also received. Second another second mask selectively blocks the formation of silicide on top of the poly. It is possible to use either or both of these masks to enhance the performance of the E-fuse 300, without adding additional masks to the design.

In accordance with features of the preferred embodiments, the areas of polysilicon that receive P+ implant have a lower sheet resistance than normal P+ gate regions and helps to maximize the voltage drop in the narrow fuse element region 306 when a programming potential is applied across the silicide formation 308.

In FIG. 4, the fabrication sequence begins with a normal CMOS p+ poly fuse shape generally designated by the reference character 400 as shown. Gate conductor polysilicon is deposited to a preferred thickness ranging from 50 to 200 nm, and patterned with the normal gate mask.

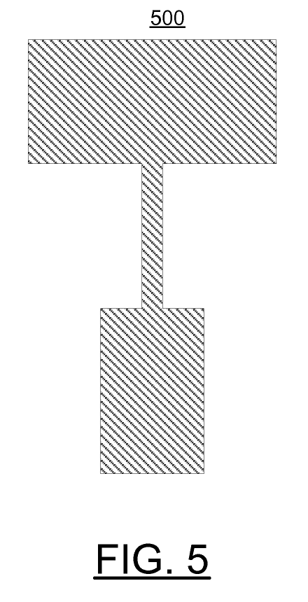

FIG. 5 illustrates a next processing step generally designated by the reference character 500 where in the course of gate conductor processing, the normal P+ gate conductor implant is made into the fuse poly shape 400.

The processing step 500 uses the heavy P+ implant to increase the conductivity of the polysilicon, while blocking the implant from other structures. The sheet resistance of the now heavily P+ doped 100 nm thick poly ranges from about 300 to 400 ohms/square. A layer of low-temperature oxide (LTO) is deposited to a preferred thickness from 5 nm to 20 nm. Then a layer of CVD nitride (20 nm-40 nm) is deposited. The purpose of the nitride is to prevent the formation of silicide in selected regions.

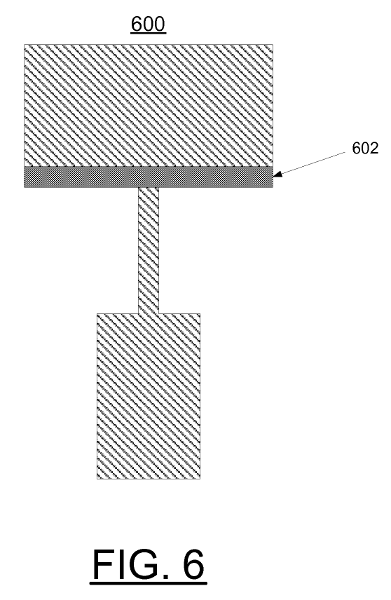

FIG. 6 illustrates a next processing step generally designated by the reference character 600 preparing the surface of the E-fuse structure to be selectively silicided. The silicidation step also forms silicide on the source-drain regions and on the gate conductors. A layer of photoresist is applied, and patterned with the second mask that selectively blocks the formation of silicide on top of the poly. The exposed portions of the thin nitride and oxide layers are removed with isotropic or directional etching in FIG. 6; and the thin insulating layers remain only in the narrow strip portion 602 of the cathode, as shown in FIG. 6.

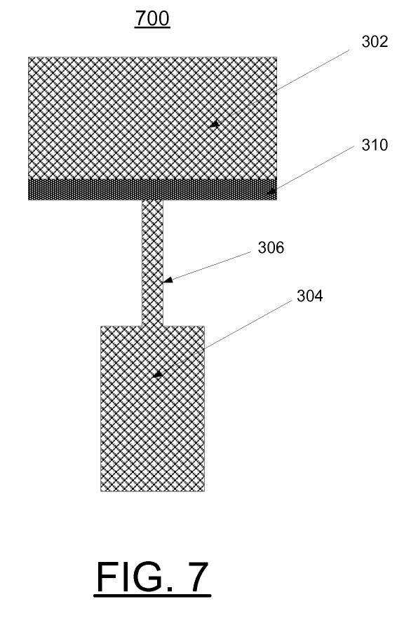

FIG. 7 illustrates a next processing step generally designated by the reference character 700 where a thin layer of silicide metal such as cobalt, nickel, tungsten, tantalum, or the like, is deposited. The substrate is then annealed which causes the metal and exposed silicon to react and form the silicide 308. The metal over insulator regions does not react and are removed with a selective isotropic etch. The resulting E-fuse structure 300 is now silicided except for the narrow unsilicided strip 310 in the cathode 302.

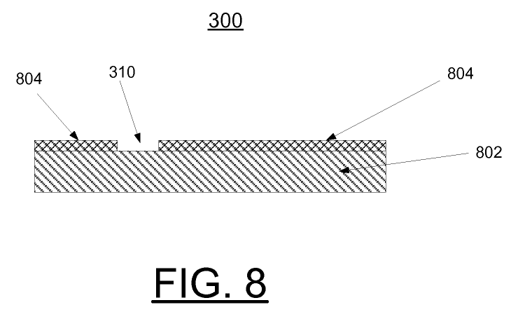

FIG. 8 is a cross-sectional view not to scale of the resulting exemplary E-fuse 300 in accordance with the preferred embodiment. E-fuse 300 includes a highly conductive or P++ implanted poly layer 802 supporting silicide regions 804 with an unsilicided portion or unsilicided gap 310. During fuse programming, due to the unsilicided gap 310 in the E-fuse's silicide, the current cannot travel in the silicide in the region of the cathode 302 of E-fuse 300. This means that electromigration will only happen in the neck 306 of E-fuse 300. This will avoid the problems with the EM taking place in the cathode rather than in the neck and causing a low post-blow resistance of the prior art E-fuse, as illustrated in FIG. 1.

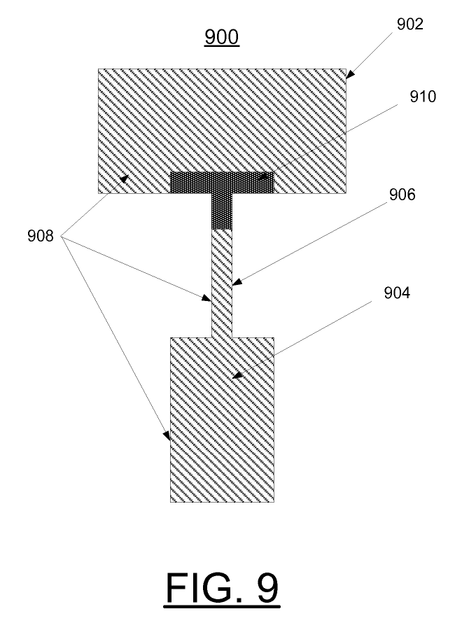

FIG. 9 illustrates another exemplary E-fuse generally designated by the reference character 900 fabricated by integrating polysilicon resistor masks in accordance with the preferred embodiment. Similar fabrication steps as in the fabrication of E-fuse 300 are performed to fabricate the second embodiment of this invention, E-fuse 900, as shown in FIG. 9.

E-fuse 900 includes a cathode 902, an anode 904, and a narrow fuse neck or fuse element 906 connected between the cathode 902 and the anode 904. A formation of silicide generally designated by the reference character 908 is formed everywhere except for a T-shaped portion 910 of the cathode 902 and the narrow fuse neck 906.

The silicide 908 is indicated by crosshatched lines, and the unsilicided T-shaped portion 910 of the cathode 902 and the narrow fuse element 906 is indicated by dots. The unsilicided T-shaped portion 910 has a series resistance that is small relative to the remainder of narrow fuse element 906.

In the E-fuse 900, the unsilicided T-shaped portion or border 910 provided adjacent to the cathode end of the silicided fuse neck 906 together with extending the cathode silicide as close as possible to the fuse neck 906, voltage drop in the unsilicided portion 910 of the cathode 902 is minimized. This reduces the requirement of a wide cathode, as shown in E-fuse 300. The E-fuse 900 may be blown without silicide migration from the cathode 902.

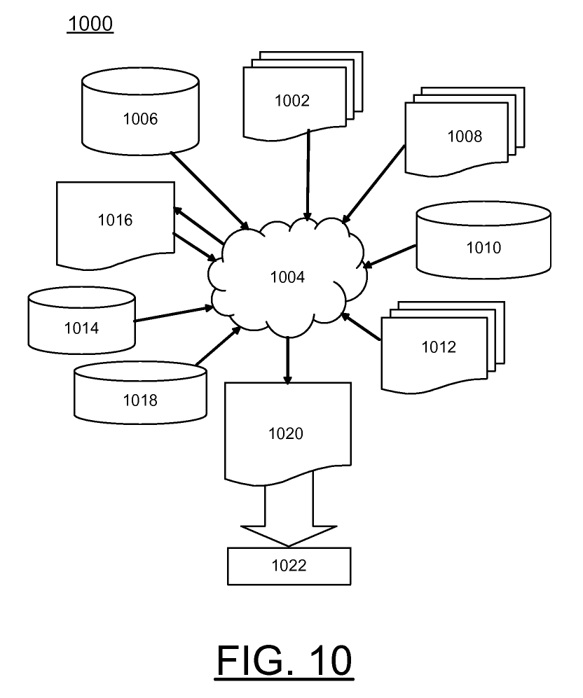

FIG. 10 shows a block diagram of an example design flow 1000. Design flow 1000 may vary depending on the type of IC being designed. For example, a design flow 1000 for building an application specific IC (ASIC) may differ from a design flow 1000 for designing a standard component. Design structure 1002 is preferably an input to a design process 1004 and may come from an IP provider, a core developer, or other design company or may be generated by the operator of the design flow, or from other sources. Design structure 1002 comprises circuit 100 in the form of schematics or HDL, a hardware-description language, for example, Verilog, VHDL, C, and the like. Design structure 1002 may be contained on one or more machine readable medium. For example, design structure 1002 may be a text file or a graphical representation of E-fuse circuits 300, 900. Design process 1004 preferably synthesizes, or translates, E-fuse circuits 300, 900 into a respective netlist 1006, where netlist 1006 is, for example, a list of wires, transistors, logic gates, control circuits, I/O, models, etc. that describes the connections to other elements and circuits in an integrated circuit design and recorded on at least one of machine readable medium. This may be an iterative process in which netlist 1006 is resynthesized one or more times depending on design specifications and parameters for the circuit.

Design process 1004 may include using a variety of inputs; for example, inputs from library elements 1008 which may house a set of commonly used elements, circuits, and devices, including models, layouts, and symbolic representations, for a given manufacturing technology, such as different technology nodes, 32 nm, 45 nm, 100 nm, and the like, design specifications 1010, characterization data 1012, verification data 1014, design rules 1016, and test data files 1018, which may include test patterns and other testing information. Design process 1004 may further include, for example, standard circuit design processes such as timing analysis, verification, design rule checking, place and route operations, and the like. One of ordinary skill in the art of integrated circuit design can appreciate the extent of possible electronic design automation tools and applications used in design process 1004 without deviating from the scope and spirit of the invention. The design structure of the invention is not limited to any specific design flow.

Design process 1004 preferably translates an embodiment of the invention as shown in FIG. 3 and FIGS. 4-8, and FIG. 9 along with any additional integrated circuit design or data (if applicable), into a respective second design structure 1020. Design structure 1020 resides on a storage medium in a data format used for the exchange of layout data of integrated circuits, for example, information stored in a GDSII (GDS2), GL1, OASIS, or any other suitable format for storing such design structures. Design structure 1020 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 3 and FIGS. 4-8, and FIG. 9. Design structure 1020 may then proceed to a stage 1022 where, for example, design structure 1020: proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A design structure embodied in a machine readable medium used in a design process, the design structure comprising:
an E-fuse including
a polysilicon layer defining a fuse shape;
said fuse shape including a cathode, an anode, and a fuse neck connected between the cathode and the anode;
a silicide formation formed on the polysilicon layer including an unsilicided portion extending over a portion of said cathode adjacent said fuse neck; and
said unsilicided portion substantially preventing current flow in the silicide formation region of the cathode with electromigration occurring in the fuse neck during fuse programming.

2. The design structure of claim 1, wherein the design structure comprises a netlist, which describes the E-fuse circuit.

3. The design structure of claim 1, wherein the design structure resides on storage medium as a data format used for the exchange of layout data of integrated circuits.

4. The design structure of claim 1, wherein the design structure includes at least one of test data files, characterization data, verification data, or design specifications.

5. The design structure of claim 1, wherein said unsilicided portion has a substantially lower resistance than a resistance of said fuse neck.

6. The design structure of claim 1, wherein said polysilicon layer is a highly conductive polysilicon layer; said polysilicon layer includes a heavily doped implant for increasing conductivity.

7. The design structure of claim 1, wherein said polysilicon layer includes a heavily doped P+ implant for increasing conductivity and to maximize a voltage drop in said fuse neck when a programming potential is applied across said silicide formation.

8. The design structure of claim 1, wherein said unsilicided portion extending over said portion of the cathode adjacent said fuse neck has a predefined width and a predefined depth to provide a substantially lower series resistance than a series resistance of said fuse neck.

9. The design structure of claim 1, wherein said unsilicided portion extending over said portion of the cathode adjacent said fuse neck is a generally T-shaped portion including an unsilicided portion extending over an adjacent portion of said fuse neck.

10. The design structure of claim 1, wherein said unsilicided portion has a defined size for providing a predefined series resistance of said unsilicided portion, whereby electromigration of said silicide layer occurs in said fuse neck and electromigration of said silicide layer is avoided in said cathode when a programming potential is applied across the silicide formation.

11. The design structure of claim 1, wherein said polysilicon layer includes an implant for increasing conductivity; said implant provided using a polysilicon resistor mask.

12. The design structure of claim 1, wherein said unsilicided portion is provided using a polysilicon resistor mask for blocking formation of silicide.

13. The design structure of claim 1, wherein said silicide formation is formed on said polysilicon layer with a silicide metal selected from the group consisting of cobalt, nickel, tungsten, and tantalum.
